(19) United States
(12) Patent Application Publication
(10) Pub. No.: US 2024/0068100 A1
(43) Pub. Date: Feb. 29, 2024

(54) WAFER SUPPORT PLATE AND SEMICONDUCTOR MANUFACTURING APPARATUS INCLUDING SAME

(71) Applicant: United Semiconductor Japan Co., Ltd., Kuwana-shi (JP)

(72) Inventor: Satoshi Inagaki, Yokkaichi (JP)

(73) Assignee: United Semiconductor Japan Co., Ltd., Kuwana-shi (JP)

(21) Appl. No.: 18/234,899

(22) Filed: Aug. 17, 2023

(30) Foreign Application Priority Data
Aug. 23, 2022 (JP) 2022-132584

(51) Int. Cl. C23C 16/458; C23C 16/455

(52) U.S. Cl. CPC C23C 16/4583; C23C 16/45568; C23C 16/4581

(57) ABSTRACT

A wafer support member that can move in the same chamber after a film has been formed on a wafer and enable processing of the film-formed wafer and a semiconductor manufacturing apparatus including the wafer support member are provided. The wafer support plate 10 includes a flat portion 1 configured to support a wafer W and an outer circumferential protruding portion 2, being disposed in a surrounding shape on an outer circumference of the flat portion 1 and being formed with a larger thickness than the wafer W. The flat portion 1 includes a perforated support portion 1A and an annular support portion 1B. The annular support portion 1B is disposed outside of the perforated support portion 1A and supports an outer circumferential end portion Wₒ of the wafer W.

### CROSS-REFERENCE TO RELATED APPLICATION

This application is based upon and claims the benefit of priority of the prior Japanese Patent Application No. 2022-132584, filed on Aug. 23, 2022, the entire contents of which are incorporated herein by reference.

### BACKGROUND OF THE INVENTION

### 1. Field of the Invention

The present disclosure relates to a wafer support plate and a semiconductor manufacturing apparatus including the same.

### 2. Description of the Prior Art

In the related art, a film forming system for forming a plurality of kinds of films in which chambers are provided for processes with different film forming materials or conditions and a wafer is transported to the chambers to form a film is known.

A wafer can be heated using a heater table and a metal film is formed, for example, using a film forming method such as a sputtering method. When film formation is completed, the wafer is transported to another processing chamber for subsequent film formation or the wafer is cooled through a cooling process according to necessity. For example, when a plurality of types of films is grown using a sputtering method, a wafer is often transported to a plurality of chambers to form films thereon, and processing chambers including a wafer transport chamber are maintained in high vacuum in order to prevent oxidation of metal films.

Various structures for supporting a wafer are known (for example, Patent Literatures 1 to 10). For example, a wafer support structure disclosed in Patent Literature 1 is characterized as a structure in which a side surface and an outer circumferential backside of a wafer are supported.

### PATENT LITERATURES

[Patent Literature 1] Japanese Laid-open Patent Publication No. 2009-182009
[Patent Literature 2] Japanese Laid-open Patent Publication No. 2000-286328
[Patent Literature 3] Japanese Laid-open Patent Publication No. 2017-228705
[Patent Literature 4] Japanese Laid-open Patent Publication No. 2016-207932
[Patent Literature 5] PCT International Publication No. WO2016/174860
[Patent Literature 6] Japanese Laid-open Patent Publication No. 2020-107857
[Patent Literature 7] Japanese Laid-open Patent Publication No. 2021-153122
[Patent Literature 8] Japanese Laid-open Patent Publication No. H6-132231
[Patent Literature 9] Japanese Laid-open Patent Publication No. H10-107126
[Patent Literature 10] Japanese Laid-open Patent Publication No. 2005-15820

In high vacuum, thermal conductivity is low, and a film-formed wafer is substantially maintained at the temperature at the time of film formation. Accordingly, when transportation requires time, a thermal history of a metal film formed on the wafer extends for a long time, and a film shape of a metal film with low heat resistance changes or a film quality of the metal film deteriorates.

The wafer support structure disclosed in Patent Literature 1 does not support a backside of a wafer. A protruding portion is provided in an outer circumferential portion, but it does not have a surrounding shape and a height (thickness) of the protruding portion is less than a height of a wafer. Accordingly, a closed space cannot be formed between a chamber inner wall and the wafer support structure using the wafer support structure. Even when a closed space is formed between an outer circumference side of the wafer support structure and the chamber inner wall using a certain method when the outer circumference side can move as an independent wafer support structure, a force applied when a pressure difference occurs between the front side and the back side of the wafer can be concentrated on the outer circumferential portion of the wafer and the probability of damage to the wafer increases.

### SUMMARY OF THE INVENTION

According to a first aspect of the present disclosure, there is provided a wafer support plate including: a flat portion configured to support a wafer; and an outer circumferential protruding portion, being disposed in a surrounding shape on an outer circumference of the flat portion and being formed with a larger thickness than the wafer, wherein the flat portion includes a perforated support portion and an annular support portion, and the annular support portion is disposed outside of the perforated support portion and supports an outer circumferential end portion of the wafer.

A second aspect of the present disclosure is the wafer support plate according to the first aspect, wherein a gas introduction pipe extending from a top surface to an inner circumferential sidewall is formed in the outer circumferential protruding portion.

A third aspect of the present disclosure is the wafer support plate according to the first or second aspect, wherein the perforated support portion includes a linear portion, and the perforated support portion includes a linear pattern, and the linear pattern is symmetric with respect to the center of the flat portion.

A fourth aspect of the present disclosure is the wafer support plate according to any one of the first to third aspects, wherein the perforated support portion includes a ring-shaped portion using the center of the flat portion as the center of a ring and a radial linear portion extending radially in a linear shape from the ring-shaped portion to the annular support portion.

A fifth aspect of the present disclosure is the wafer support plate according to any one of the first to third aspects, wherein the perforated support portion includes a radial linear portion extending radially in a linear shape from the center of the flat portion to the annular support portion.

A sixth aspect of the present disclosure is the wafer support plate according to any one of the first to third aspects, wherein the perforated support portion includes a radial linear portion extending radially in a linear shape from the center of the flat portion to the annular support portion and a plurality of ring-shaped portions disposed concentrically using the center of the flat portion as a center of concentric circles.

A seventh aspect of the present disclosure is the wafer support plate according to any one of the first to third aspects, wherein the perforated support portion includes a ring-shaped portion centered the center of the flat portion, a radial linear portion extending radially in a linear shape from the ring-shaped portion to the annular support portion, and a non-radial linear portion extending non-radially in a linear shape from the ring-shaped portion to the annular support portion.

An eighth aspect of the present disclosure is the wafer support plate according to any one of the first to seventh aspects, wherein the perforated support portion includes a linear portion with a width equal to 3 mm, more than 3 mm and less than 30 mm, or equal to 30 mm.

A ninth aspect of the present disclosure is the wafer support plate according to any one of the first to eighth aspects, wherein the gas introduction pipe of the outer circumferential protruding portion includes a gas introduction hole disposed in the top surface, a gas discharge hole disposed in the inner circumferential sidewall, and a gas flow channel allowing the gas introduction hole to communicate with the gas discharge hole.

A tenth aspect of the present disclosure is the wafer support plate according to the ninth aspect, wherein the gas flow channel is disposed in a surrounding shape in the outer circumferential protruding portion.

An eleventh aspect of the present disclosure is the wafer support plate according to the ninth or tenth aspect, wherein the gas introduction pipe includes a plurality of gas discharge holes disposed to be separated from each other.

A twelfth aspect of the present disclosure is the wafer support plate according to any one of the first to eleventh aspects, wherein the wafer support plate is formed with a heat resistant material and a melting point of the heat resistance material is equal to or higher than 500° C.

A thirteenth aspect of the present disclosure is the wafer support plate according to the twelfth aspect, wherein the heat resistant material includes one of a steel use stainless, a titanium alloy, a nickel alloy, a cobalt alloy, a tantalum alloy, and a molybdenum alloy or a combination thereof.

According to a fourteenth aspect of the present disclosure, there is provided a semiconductor manufacturing apparatus including: the wafer support plate according to any one of the first to thirteenth aspects; a heater table including a mounting surface configured to mount the wafer, a groove pattern being formed on the mounting surface; a moving mechanism configured to move the wafer support plate in a vertical direction; a chamber accommodating the wafer support plate and the heater table; and a gas supply pipe disposed in an outer wall of the chamber, wherein a part of the perforated support portion in the wafer support plate is accommodated in the groove pattern.

A fifteenth aspect of the present disclosure is the semiconductor manufacturing apparatus according to the fourteenth aspect, wherein the gas supply pipe serves also as a gas discharge pipe.

A sixteenth aspect of the present disclosure is the semiconductor manufacturing apparatus according to the fourteenth aspect, further including a gas discharge pipe disposed in an outer wall of the chamber.

A seventeenth aspect of the present disclosure is the semiconductor manufacturing apparatus according to the fourteenth aspect, further including a support pin supporting the outer circumferential protruding portion, wherein the moving mechanism moves the wafer support plate in the vertical direction by moving the support pin in the vertical direction.

An eighteenth aspect of the present disclosure is the semiconductor manufacturing apparatus according to the seventeenth aspect, wherein the support pin support the outer circumferential protruding portion with a bottom surface of the outer circumferential protruding portion.

A nineteenth aspect of the present disclosure is the semiconductor manufacturing apparatus according to the seventeenth aspect, wherein the support pin support the outer circumferential protruding portion with a top surface of the outer circumferential protruding portion.

A twentieth aspect of the present disclosure is the semiconductor manufacturing apparatus according to the seventeenth aspect, wherein the support pin includes a first part protruding from an outer circumferential side surface of the outer circumferential protruding portion and a second part extending upward to be connected with the first part, and the support pin supports the outer circumferential protruding portion.

The object and advantages of the invention will be realized and attained by means of the elements and combinations particularly pointed out in the claims.

It is to be understood that both the foregoing general description and the following detailed description are exemplary and explanatory and are not restrictive of the invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic plan view illustrating a configuration of a wafer support plate according to a first embodiment and FIG. 1B is a schematic sectional view of the wafer support plate illustrated in FIG. 1A which is cut along line X-X.

FIG. 2A is a schematic plan view of a wafer and the wafer support plate on which the wafer is not still placed and FIG. 2B is a schematic plan view of the wafer support plate on which the wafer is placed.

FIG. 3 is a schematic plan view illustrating a configuration of a modified example of the wafer support plate illustrated in FIGS. 1A and 1B.

FIG. 4 is a schematic plan view illustrating a configuration of another modified example of the wafer support plate illustrated in FIGS. 1A and 1B.

FIG. 5 is a schematic plan view illustrating a configuration of another modified example of the wafer support plate illustrated in FIGS. 1A and 1B.

FIG. 6A is a schematic plan view illustrating a configuration of a wafer support plate according to a second embodiment and FIG. 6B is a schematic sectional view of the wafer support plate illustrated in FIG. 6A which is cut along line X-X.

FIG. 7A is a schematic plan view illustrating a configuration of a modified example of the wafer support plate illustrated in FIGS. 6A and 6B and FIG. 7B is a schematic plan view illustrating a configuration of another modified example different from the modified example illustrated in FIG. 7A.

FIG. 8A is a schematic plan view illustrating a configuration of another modified example of the wafer support plate illustrated in FIGS. 6A and 6B, FIG. 8B is a schematic plan view illustrating a configuration of another modified example of the wafer support plate illustrated in FIGS. 6A and 6B, and FIG. 8C is a schematic plan view illustrating a configuration of another modified example of the wafer support plate illustrated in FIGS. 6A and 6B.

FIGS. 9A and 9B are schematic sectional views illustrating a configuration of a semiconductor manufacturing apparatus according to the first embodiment, where FIG. 9A illustrates a setup when a film is formed and FIG. 9B illustrates a setup when a wafer W is cooled.

FIG. 10A is a schematic plan view in a state in which the wafer support plate is not still placed on a heater table and FIG. 10B is a schematic plan view in a state in which the wafer support plate is placed on the heater table.

FIG. 11A is a schematic plan view illustrating a configuration of another modified example of the heater table illustrated in FIGS. 10A and 10B, FIG. 11B is a schematic plan view illustrating a configuration of another modified example different from the modified example illustrated in FIG. 11A, and FIG. 11C is a schematic plan view illustrating a configuration of another modified example different from the modified example illustrated in FIG. 11A.

FIGS. 12A and 12B are schematic sectional views illustrating a configuration of a semiconductor manufacturing apparatus according to the second embodiment, where FIG. 12A illustrates a setup when a film is formed and FIG. 12B illustrates a setup when a wafer W is cooled.

FIG. 13A is a schematic plan view in a state in which the wafer support plate is not still placed on a heater table and FIG. 13B is a schematic plan view in a state in which the wafer support plate is placed on the heater table.

FIG. 14A is a schematic plan view illustrating a configuration of another modified example of the heater table illustrated in FIGS. 13A and 13B, FIG. 14B is a schematic plan view illustrating a configuration of another modified example different from the modified example illustrated in FIG. 14A, and FIG. 14C is a schematic plan view illustrating a configuration of another modified example different from the modified example illustrated in FIG. 14A.

FIGS. 15A and 15B are schematic sectional views illustrating a configuration of a semiconductor manufacturing apparatus according to a third embodiment, where FIG. 15A illustrates a setup when a film is formed and FIG. 15B illustrates a setup when a wafer W is cooled.

FIGS. 16A and 16B are schematic sectional views illustrating a configuration of another example of the semiconductor manufacturing apparatus according to the third embodiment, where FIG. 16A illustrates a setup when a film is formed and FIG. 16B illustrates a setup when a wafer W is cooled.

FIG. 17A is a schematic plan view illustrating a positional relationship between a support pin, a lift pin, and a fork in the semiconductor manufacturing apparatus illustrated in FIGS. 15A and 15B and FIG. 17B is a schematic plan view illustrating a positional relationship between a support pin, a lift pin, and a fork in the semiconductor manufacturing apparatus illustrated in FIGS. 16A and 16B.

### DETAILED DESCRIPTION

Hereinafter, the present disclosure will be described in detail with appropriate reference to the accompanying drawings. In the drawings referred to in the following description, featured parts can be enlarged for the convenience of easy understanding of features, and dimensional ratios of constituents can be different from actual ones. Dimensions or the like exemplified in the following description are examples, but the present disclosure is not limited thereto and the dimensions or the like can be appropriately modified as long as advantageous effects of the present disclosure can be achieved.

In the following description, unless otherwise mentioned, a configuration described in one embodiment can be applied to other embodiments.

[Wafer Support Plate]

### First Embodiment

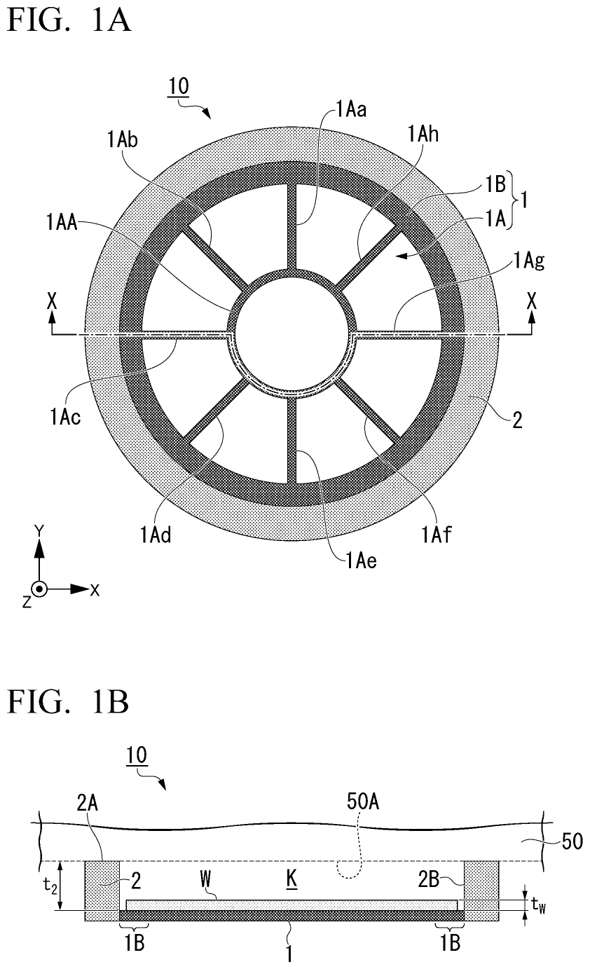

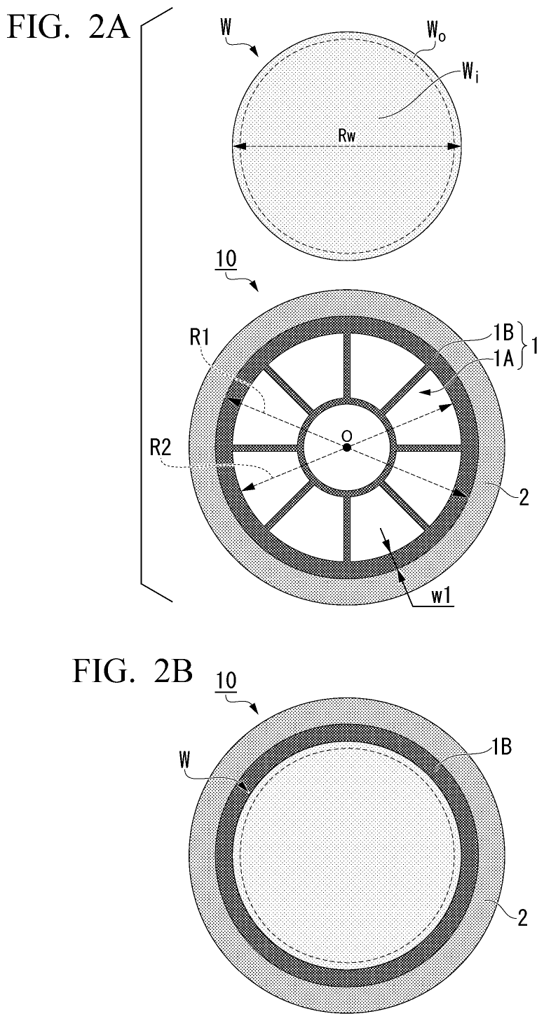

FIG. 1A is a schematic plan view illustrating a configuration of a wafer support plate according to a first embodiment and FIG. 1B is a schematic sectional view of the wafer support plate illustrated in FIG. 1A which is cut by line X-X. FIG. 2A is a schematic plan view of a wafer and the wafer support plate on which the wafer is not still placed and FIG. 2B is a schematic plan view of the wafer support plate on which the wafer is placed.

The wafer support plate 10 illustrated in FIGS. 1A and 1B includes a flat portion 1 configured to support a wafer W and an outer circumferential protruding portion 2 that is disposed in a surrounding shape on an outer circumference of the flat portion 1 and is formed with a larger thickness than the wafer W. The flat portion 1 includes a perforated support portion 1A and an annular support portion 1B, and the annular support portion 1B is disposed outside of the perforated support portion 1A and is configured to support an outer circumferential end portion Wₒ of the wafer W.

A wafer support plate according to the present disclosure is a member that is used in a semiconductor manufacturing apparatus including a heater table that heats a wafer. A part of the wafer support plate according to the present disclosure is accommodated in a groove formed on a mounting surface of a heater table after a wafer W has been mounted on the heater table at the time of forming a film such that the wafer support plate can be separated from the wafer W. The wafer support plate according to the present disclosure, along with the inner wall of the chamber and the wafer W, is configured to form a closed space in which a cooling gas can be held when cooling the wafer W after film formation.

<Flat Portion>

The flat portion 1 includes a perforated support portion LA on which an inner portion Wᵢ of the wafer W is mounted and an annular support portion 1B on which an outer circumferential end portion Wₒ located on outer circumferential of the inner portion Wᵢ is mounted. The flat portion 1 includes the same shape as the wafer W in a plan view. The flat portion 1 includes a circular shape in the case that the wafer W has a circular shape. The perforated support portion 1A includes a circular shape, and the annular support portion 1B has a ring shape.

The flat portion 1 includes a support function of supporting the wafer W, an accommodation function of accommodating a part of the flat portion in a groove formed on the mounting surface of the heater table at the time of forming a film, and a closing function of forming a closed space along with an inner wall of a chamber, the outer circumferential protruding portion, and the wafer W when a film-formed wafer W is processed after film formation (for example, being cooled or being heated).

The support function of the flat portion 1 is performed by the perforated support portion 1A and the annular support portion 1B, the accommodation function is performed by the perforated support portion 1A, and the closing function is performed mainly by the annular support portion 1B.

An example of a temperature adjusting process of the film-formed wafer W is cooling after high-temperature film formation. In addition to this, examples of the temperature adjusting process include heating after low-temperature film formation and returning to a normal temperature after extremely low-temperature processing. Accordingly, the temperature adjusting process of a wafer W is not limited to the cooling after high-temperature film formation.

In the following, cooling after high-temperature film formation will be mainly described as an example of the temperature adjusting process of a film-formed wafer W.

The thickness of the flat portion 1 may be, for example, equal to 3 mm, more than 3 mm and less than 30 mm, or equal to 30 mm.

The perforated support portion is a member including perforated parts and is a member including a part which is accommodated in a groove of a pattern of grooves (a groove pattern) formed on the wafer mounting surface of the heater table. The perforated support portion 1A exhibits the accommodation function since it includes a part accommodated in the groove of the groove pattern on the mounting surface of the heater table. Accordingly, a pattern of the part of the perforated support portion LA accommodated in the groove is determined according to the groove pattern on the wafer mounting surface of the heater table which is used.

The perforated support portion 1A illustrated in FIGS. 1A and 1B is a linear support portion including only linear portions. As long as the accommodation function is exhibited, the perforated support portion 1A may include a part (a nonlinear portion) other than the linear portions. When the perforated support portion LA is a linear support portion including only the linear portions, the perforated support portion 1A preferably includes a linear pattern which is symmetric with respect to the center O of the flat portion.

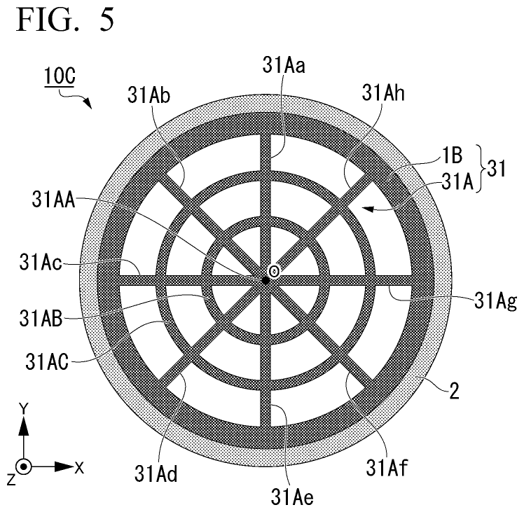

In the following, a case in which the perforated support portion 1A is a linear support portion will be described with reference to the drawings. In this specification, a part in which a linear portion and a linear portion meet (for example, a point-shaped portion 21AA in FIG. 4 and a point-shaped portion 31AA in FIG. 5) is not included in the nonlinear portion. Accordingly, a perforated support portion 21A illustrated in FIG. 4 and a perforated support portion 31A illustrated in FIG. 5 are linear support portions.

The perforated support portion 1A includes a ring-shaped portion 1AA centered the center O of the flat portion 1 and eight radial linear portions 1Aa, 1Ab, 1Ac, 1Ad, 1Ae, 1Af, 1Ag, and 1Ah extending radially in a linear shape from the ring-shaped portion 1AA to the annular support portion 1B. The perforated support portion 1A illustrated in FIG. 1A includes a configuration including the eight radial linear portions, but the number of radial linear portions is not limited to eight and may be seven or less or nine or more.

The eight radial linear portions include four groups of which each include two radial linear portions (radial linear portions 1Aa and 1Ae, radial linear portions 1Ab and 1Af, radial linear portions 1Ac and 1Ag, and radial linear portions 1Ad and 1Ah) disposed at positions diagonally symmetric with respect to the circle center O. The disposition of the radial linear portions in the perforated support portion 1A includes symmetry, but is not limited to the configuration with symmetry.

Here, a “radial shape” in this specification indicates a shape in which a plurality of lines extends linearly to the surroundings from one point as the center. The “radial shape” includes both those lines extending from the center as a starting point and each of those lines extending from each of points separated from the center as a starting point. The eight radial linear portions 1Aa, 1Ab, 1Ac, 1Ad, 1Ae, 1Af, 1Ag, and 1Ah extend linearly from each of positions on the ring-shaped portion 1AA separated from the center O of the flat portion 1 as start points. Each of the eight radial linear portions is disposed on each of straight lines extending from the center O of the flat portion 1 to the surroundings and thus extend “radially”.

The width of the perforated support portion 1A may be, for example, equal to 3 mm, more than 3 mm and less than 30 mm, or equal to 30 mm.

The annular support portion 1B is formed continuously in a circular shape. “Continuously” means that connecting continuously without sporadic parts or intermittent parts. This is for exhibiting the closing function.

It is preferable that the thickness of the annular support portion 1B be constant. This is for reliably exhibiting the closing function and is because the period use can be extended as compared with the case where the thickness is not constant.

The width of the annular support portion 1B may be, for example, equal to 2 mm, more than 2 mm and less than 100 mm, or equal to 100 mm.

It is preferable that the width w1 of the annular support portion 1B be constant as illustrated in FIG. 1A. This is because the period of use can be extended as compared with the case where the thickness is not constant.

The outer diameter R1 and inner diameter R2 of the annular support portion 1B are set to include a relationship with the diameter Rw of the wafer W such that R2<Rw<R1. In order to form a closed space by cooperation of the inner wall of the chamber, the outer circumferential protruding portion, and the wafer W, it is necessary to satisfy a dimensional relationship that the perforated support portion 1A is not visible in a view from a direction (Z direction) in which the wafer W and the flat portion 1 overlap when the wafer W is mounted on the flat portion 1. When the perforated support portion 1A is visible, a gap is formed in the view from the overlapping direction and thus the closed space is not formed.

Since a gap cannot be formed even when the wafer W deviates, it is preferable that the outer diameter R1 and the inner diameter R2 of the annular support portion 1B and the diameter Rw of the wafer W satisfy a relationship expressed by Expression (1).

$$\begin{matrix}[ Meth . 1 ] & \\ \frac{1}{2} ( R 1 + R 2 ) < Rw & ( 1 )\end{matrix}$$

<Outer Circumferential Protruding Portion>

FIG. 1B illustrates a state in which the wafer W is mounted on the wafer support plate 10. In a semiconductor manufacturing apparatus which will be described later, a chamber 50 is indicated by a dotted line to illustrate the disposition of the wafer support plate 10 and the chamber 50 in order to illustrate that the wafer support plate 10 and the inner wall 50A of the chamber 50 forma closed space K when the film-formed wafer W is cooled.

The outer circumferential protruding portion 2 includes the closing function of forming a closed space along with the inner wall of the chamber and the wafer W when the wafer W is cooled. Specifically, a top surface 2A of the outer circumferential protruding portion 2 can be brought into contact with the inner wall 50A of the chamber 50 when the wafer W is cooled, and thus the closed space K can be formed in a state in which the wafer W is accommodated in the closed space K.

In order to exhibit this function, the outer circumferential protruding portion 2 is formed continuously in the circular ring.

The outer circumferential protruding portion 2 includes an accommodation space securing function of accommodating the wafer W in the closed space K such that the wafer W does not come into contact with the inner wall 50A of the chamber 50 when the top surface 2A of the outer circumferential protruding portion 2 is brought into contact with the inner wall 50A of the chamber 50 at the time of cooling the wafer W. For this purpose, a thickness t₂ of the outer circumferential protruding portion 2 is set to be larger than a thickness t_{w} of the wafer W.

Since the thickness t_{w} of the wafer W is generally equal to or less than 0.8 mm, the thickness t₂ of the outer circumferential protruding portion 2 is equal to or greater than 2 mm. It is preferable that the thickness t₂ of the outer circumferential protruding portion 2 range from 5 mm to 60 mm.

The width of the outer circumferential protruding portion 2 may be, for example, equal to 5 mm, more than 5 mm and less than 100 mm, or equal to 100 mm.

In order to enhance air tightness with the inner wall 50A of the chamber 50, for example, a groove may be formed on the top surface 2A of the outer circumferential protruding portion 2 and a known member for enhancing air tightness such as an O-ring may be disposed.

As will be described later, the wafer W disposed in the closed space K may be cooled by introducing a cooling gas into the closed space K. It is possible to enhance cooling efficiency by disposing a cooling unit for cooling an outer wall 50B of the chamber 50 near the inner wall 50A in which the closed space K is formed with a refrigerant (for example, a coolant). The present disclosure is not limited to cooling, but if the temperature of the processed wafer is low, it may be heated by a heater or returned to room temperature depending on the application by adopting necessary member.

It is preferable that the wafer support plate 10 includes heat resistance for the purpose of use in forming a metal film in a semiconductor manufacturing apparatus. It is preferable that the wafer support plate 10 is formed with, for example, a heat resistant material of which a melting point is equal to or higher than 500° C. A material selected from a group including a steel use stainless (hereinafter abbreviated to SUS), a titanium alloy, a nickel alloy, a cobalt alloy, a tantalum alloy, and a molybdenum alloy may be used as such a heat resistant material. The materials which are described above as an example of the heat resistant material may be used in combination.

The wafer support plate 10 may be manufactured by bonding the flat portion 1 and the outer circumferential protruding portion 2 which are separate using a known method, or may be shaped as a unified member through casting, forging, cutting, or the like.

### Modified Example 1

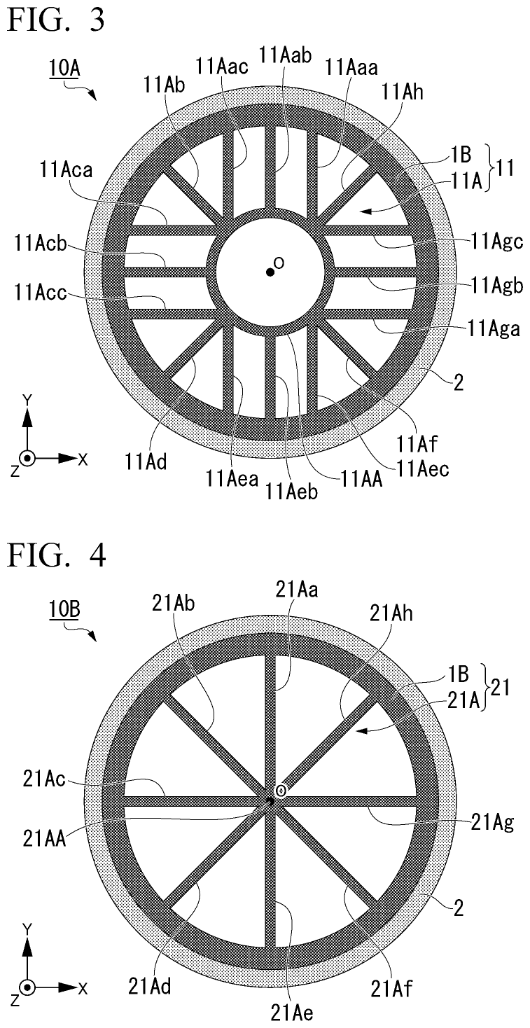

FIG. 3 is a schematic plan view illustrating a configuration of a modified example of the wafer support plate illustrated in FIGS. 1A and 1B.

The wafer support plate illustrated in FIG. 3 is different from the wafer support plate illustrated in FIGS. 1A and 1B in the configuration of the flat portion.

In the following, the same elements as in the wafer support plate illustrated in FIGS. 1A and 1B will be referred to by the same reference signs and description thereof will be omitted. The same features as the flat portion of the wafer support plate illustrated in FIGS. 1A and 1B will not be described.

The wafer support plate 10A illustrated in FIG. 3 is the same as the wafer support plate 10 illustrated in FIGS. 1A and 1B in that it includes a flat portion 11 configured to support a wafer W and an outer circumferential protruding portion 2 that is disposed in a surrounding shape on an outer circumference of the flat portion 11 and is formed with a larger thickness than the wafer W, and the flat portion 11 includes a perforated support portion 11A and an annular support portion 1B that is disposed outside of the perforated support portion 11A and is configured to support an outer circumferential end portion W. of the wafer W. The wafer support plate 10A is the same as the wafer support plate 10 illustrated in FIGS. 1A and 1B in that the perforated support portion 11A includes a ring-shaped portion 11AA with the center O of the flat portion 11 as a circle center and radial linear portions extending radially in a linear shape from the ring-shaped portion 11AA to the annular support portion 1B.

On the other hand, the wafer support plate 10A is different from the wafer support plate 10 illustrated in FIGS. 1A and 1B in that the perforated support portion 11A includes non-radial linear portions extending non-radially in a linear shape from the ring-shaped portion 11AA to the annular support portion 1B. That is, eight radial linear portions 11Aab, 11Ab, 11Acb, 11Ad, 11Aeb, 11Af, 11Agb, and 11Ah are disposed on lines extending radially from the center O of the flat portion 11, but eight non-radial linear portions 11Aaa, 11Aac, 11Aca, 11Acc, 11Aea, 11Aec, 11Aga, and 11Agc are not disposed on lines extending radially in a linear shape from the center O of the flat portion 11. The non-radial linear portions 11Aaa and 11Aac extend in parallel to the radial linear portion 11Aab, the non-radial linear portions 11Aca and 11Acc extend in parallel to the radial linear portion 11Acb, the non-radial linear portions 11Aea and 11Aec extend in parallel to the radial linear portion 11Aeb, and the non-radial linear portions 11Aga and 11Agc extend in parallel to the radial linear portion 11Agb.

The eight radial linear portions include four groups of which each include two radial linear portions (radial linear portions 11Aab and 11Aeb, radial linear portions 11Ab and 11Af, radial linear portions 11Acb and 11Agb, and radial linear portions 11Ad and 11Ah) disposed at positions diagonally symmetric with respect to the circle center O. On the other hand, the eight non-radial linear portions include four groups of which each include two non-radial linear portions (non-radial linear portions 11Aaa and 11Aec, non-radial linear portions 11Aac and 11Aea, non-radial linear portions 11Aca and 11Agc, and non-radial linear portions 11Acc and 11Aga) disposed on lines without passing through the circle center O.

The perforated support portion 11A illustrated in FIG. 3 includes a configuration including eight radial linear portions and eight non-radial linear portions, but the number of radial linear portions and the number of non-radial linear portions are not limited to eight and may be seven or less or nine or more. The number of radial linear portions and the number of radial linear portions may be different.

### Modified Example 2

FIG. 4 is a schematic plan view illustrating a configuration of another modified example of the wafer support plate illustrated in FIGS. 1A and 1B.

The wafer support plate illustrated in FIG. 4 is different from the wafer support plate illustrated in FIGS. 1A and 1B in the configuration of the flat portion.

In the following, the same elements as in the wafer support plate illustrated in FIGS. 1A and 1B will be referred to by the same reference signs and description thereof will be omitted. The same features as the flat portion of the wafer support plate illustrated in FIGS. 1A and 1B will not be described.

The wafer support plate 10B illustrated in FIG. 4 is the same as the wafer support plate 10 illustrated in FIGS. 1A and 1B in that it includes a flat portion 21 configured to support a wafer W and an outer circumferential protruding portion 2 that is disposed in a surrounding shape on an outer circumference of the flat portion 21 and is formed with a larger thickness than the wafer W, and the flat portion 21 includes a perforated support portion 21A and an annular support portion 1B that is disposed outside of the perforated support portion 21A and is configured to support an outer circumferential end portion Wₒ of the wafer W.

On the other hand, the perforated support portion 21A does not include a ring-shaped portion and includes a point-shaped portion 21AA at the center O of the flat portion 21 and radial linear portions extending radially in a linear shape from the point-shaped portion 21AA to the annular support portion 1B instead. That is, radial linear portions 21Aa, 21Ab, 21Ac, 21Ad, 21Ae, 21Af, 21Ag, and 21Ah are disposed on lines extending radially from the center O of the flat portion 21. The eight radial linear portions include four groups of which each include two radial linear portions (radial linear portions 21Aa and 21Ae, radial linear portions 21Ab and 21Af, radial linear portions 21Ac and 21Ag, and radial linear portions 21Ad and 21Ah) disposed at positions diagonally symmetric with respect to the circle center O.

The perforated support portion 21A illustrated in FIG. 4 includes a configuration including eight radial linear portions, but the number of radial linear portions is not limited to eight and may be seven or less or nine or more.

### Modified Example 3

FIG. 5 is a schematic plan view illustrating a configuration of another modified example of the wafer support plate illustrated in FIGS. 1A and 1B.

The wafer support plate illustrated in FIG. 5 is different from the wafer support plate illustrated in FIGS. 1A and 1B in the configuration of the flat portion.

In the following description, the same elements as in the wafer support plate illustrated in FIGS. 1A and 1B will be referred to by the same reference signs and description thereof will be omitted. The same features as the flat portion of the wafer support plate illustrated in FIGS. 1A and 1B will not be described.

The wafer support plate 10C illustrated in FIG. 5 is the same as the wafer support plate 10 illustrated in FIGS. 1A and 1B in that it includes a flat portion 31 configured to support a wafer W and an outer circumferential protruding portion 2 that is disposed in a surrounding shape on an outer circumference of the flat portion 31 and is formed with a larger thickness than the wafer W. The flat portion 31 includes a perforated support portion 31A and an annular support portion 1B, and the annular support portion 1B is disposed outside of the perforated support portion 31A and is configured to support an outer circumferential end portion Wₒ of the wafer W.

On the other hand, the perforated support portion 31A includes a point-shaped portion 31AA at the center O of the flat portion 31, ring-shaped portions 31AB and 31AC disposed concentrically with the center O as a center of concentric circles, and radial linear portions extending radially in a linear shape from the point-shaped portion 31AA to the annular support portion 1B.

The radial linear portions 31Aa, 31Ab, 31Ac, 31Ad, 31Ae, 31Af, 31Ag, and 31Ah are disposed on lines extending radially from the center O of the flat portion 31. The eight radial linear portions include four groups of which each include two radial linear portions (radial linear portions 31Aa and 31Ae, radial linear portions 31Ab and 31Af, radial linear portions 31Ac and 31Ag, and radial linear portions 31Ad and 31Ah) disposed at positions diagonally symmetric with respect to the circle center O.

The perforated support portion 31A illustrated in FIG. 5 includes a configuration including eight radial linear portions, but the number of radial linear portions is not limited to eight and may be seven or less or nine or more.

The perforated support portion 31A illustrated in FIG. 5 includes a configuration including two ring-shaped portions, but the number of ring-shaped portions is not limited to two and may be one or three or more.

### Second Embodiment

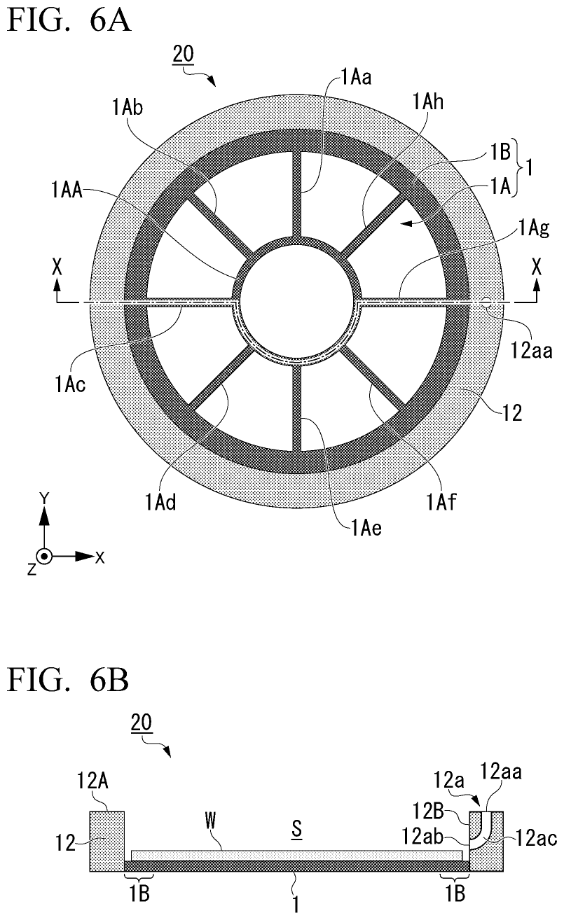

FIG. 6A is a schematic plan view illustrating a configuration of a wafer support plate according to a second embodiment and FIG. 6B is a schematic sectional view of the wafer support plate illustrated in FIG. 6A which is cut by line X-X.

The wafer support plate according to the second embodiment is mainly different from the wafer support plate according to the first embodiment in which the outer circumferential protruding portion includes a gas introduction pipe.

In the following, the same elements as in the wafer support plate according to the first embodiment will be referred to by the same reference signs and description thereof will be omitted.

Since the wafer support plate according to the second embodiment includes a configuration in which the outer circumferential protruding portion includes a gas introduction pipe, a wafer W can be cooled by introducing a cooling gas into a closed space from a gas supply pipe disposed in the outer wall of the chamber via the gas introduction pipe of the outer circumferential protruding portion after the closed space has been formed along with the inner wall of the chamber and the wafer W.

The wafer support plate 20 illustrated in FIGS. 6A and 6B includes a flat portion 1 configured to support a wafer W and an outer circumferential protruding portion 12 that is disposed in a surrounding shape on an outer circumference of the flat portion 1 and is formed with a larger thickness than the wafer W. The flat portion 1 includes a perforated support portion 1A and an annular support portion 1B, and the annular support portion 1B is disposed outside of the perforated support portion 1A and is configured to support an outer circumferential end portion W. of the wafer W. The outer circumferential protruding portion 12 includes a gas introduction pipe 12a including a gas introduction hole 12aa disposed in a top surface 12A, a gas discharge hole 12ab disposed in an inner circumferential sidewall 12B, and a gas flow channel 12ac allowing the gas introduction hole 12aa and the gas discharge hole 12ab to communicate with each other.

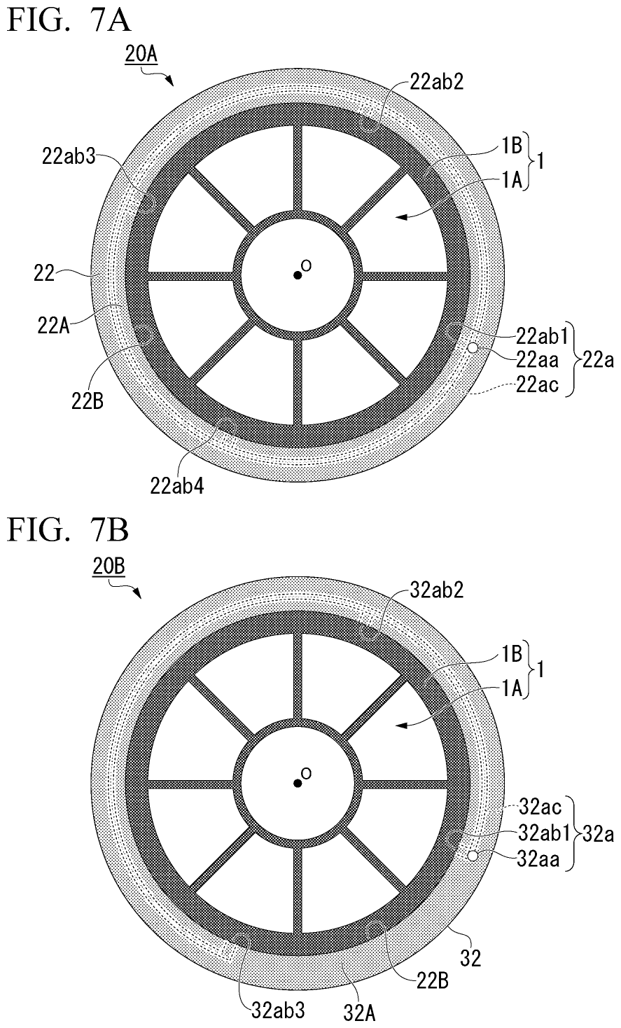

The gas flow channel may include a configuration in which it does not circulate along the outer circumferential protruding portion but connects the gas introduction hole and the gas discharge hole as illustrated in FIG. 6B or may include a configuration in which it circulates along the outer circumferential protruding portion and connects the gas introduction hole and the gas discharge hole as illustrated in FIGS. 7A and 7B.

The wafer support plate 20 illustrated in FIGS. 6A and 6B includes the same configuration as the wafer support plate 10 illustrated in FIGS. 1A and 1B in the flat portion, but may include the flat portion illustrated in one of FIGS. 3 to 5.

### Modified Examples 1 and 2

FIGS. 7A and 7B are schematic plan views illustrating a configuration of a modified example of the wafer support plate illustrated in FIGS. 6A and 6B. The modified example illustrated in FIGS. 7A and 7B is different from the wafer support plate 20 illustrated in FIGS. 6A and 6B in the configuration of the gas introduction pipe, specifically, in the length of the gas flow channel and the number of gas discharge holes.

In the following, the same elements as in the wafer support plate illustrated in FIGS. 6A and 6B will be referred to by the same reference signs and description thereof will be omitted. The same features as the flat portion of the wafer support plate illustrated in FIGS. 6A and 6B will not be described.

The wafer support plate 20A according to Modified Example 1 illustrated in FIG. 7A includes a flat portion 1 configured to support a wafer W and an outer circumferential protruding portion 22 that is disposed in a surrounding shape on an outer circumference of the flat portion 1 and is formed with a larger thickness than the wafer W. The flat portion 1 includes a perforated support portion 1A and an annular support portion 1B, and the annular support portion 1B is disposed outside of the perforated support portion 1A and is configured to support an outer circumferential end portion Wₒ of the wafer W. The outer circumferential protruding portion 22 includes a gas introduction pipe 22a including a gas introduction hole 22aa disposed in a top surface 22A, four gas discharge hole 22ab1, 22ab2, 22ab3, and 22ab4 disposed in an inner circumferential sidewall, and a gas flow channel 22ac allowing the gas introduction hole 22aa and the gas discharge holes 22ab1, 22ab2, 22ab3, and 22ab4 to communicate with each other.

In the drawing, the gas flow channel 22ac disposed in the outer circumferential protruding portion 22 is not actually visible, but is indicated by a dotted line for the purpose of illustrating the disposed configuration.

In the wafer support plate 20A illustrated in FIG. 7A, the gas flow channel 22ac is formed to circulate over one round of the outer circumferential protruding portion 22, and gas can be introduced from four gas discharge holes 22ab1, 22ab2, 22ab3, and 22ab4 disposed at equal intervals.

The wafer support plate 20A illustrated in FIG. 7A includes four gas discharge holes, but the number of gas discharge holes is not limited to four and may be three or less or five or more. An arbitrary number of gas discharge holes may be disposed at equal intervals or at unequal intervals at arbitrary positions of the gas flow channel 22ac.

The wafer support plate 20B according to Modified Example 2 illustrated in FIG. 7B includes a flat portion 1 configured to support a wafer W and an outer circumferential protruding portion 32 that is disposed in a surrounding shape on an outer circumference of the flat portion 1 and is formed with a larger thickness than the wafer W. The flat portion 1 includes a perforated support portion 1A and an annular support portion 1B, and the annular support portion 1B is disposed outside of the perforated support portion 1A and is configured to support an outer circumferential end portion Wₒ of the wafer W. The outer circumferential protruding portion 32 includes a gas introduction pipe 32a including a gas introduction hole 32aa disposed in a top surface 32A, three gas discharge hole 32ab1, 32ab2, and 32ab3 disposed in an inner circumferential sidewall, and a gas flow channel 32ac allowing the gas introduction hole 32aa and the gas discharge holes 32ab1, 32ab2, and 32ab3 to communicate with each other.

In the drawing, the gas flow channel 32ac disposed in the outer circumferential protruding portion 32 is not actually visible, but is indicated by a dotted line for the purpose of illustrating the disposed configuration.

In the wafer support plate 20B illustrated in FIG. 7B, the gas flow channel 32ac is formed in a surrounding shape over about ¾ circumference of the outer circumferential protruding portion 32, and gas can be introduced from the three gas discharge holes 32ab1, 32ab2, and 32ab3.

The extension length of the gas flow channel 32ac is not limited to ¾ round and may be less than one round with an arbitrary length.

The wafer support plate 20B illustrated in FIG. 7B includes three gas discharge holes at three positions including a start end and a termination end of the gas flow channel 32ac and an intermediate position therebetween, but the number of gas discharge holes is not limited to three and may be two or less or four or more. An arbitrary number of gas discharge holes may be disposed at equal intervals or at unequal intervals at arbitrary positions of the gas flow channel 32ac.

### Modified Examples 3 to 5

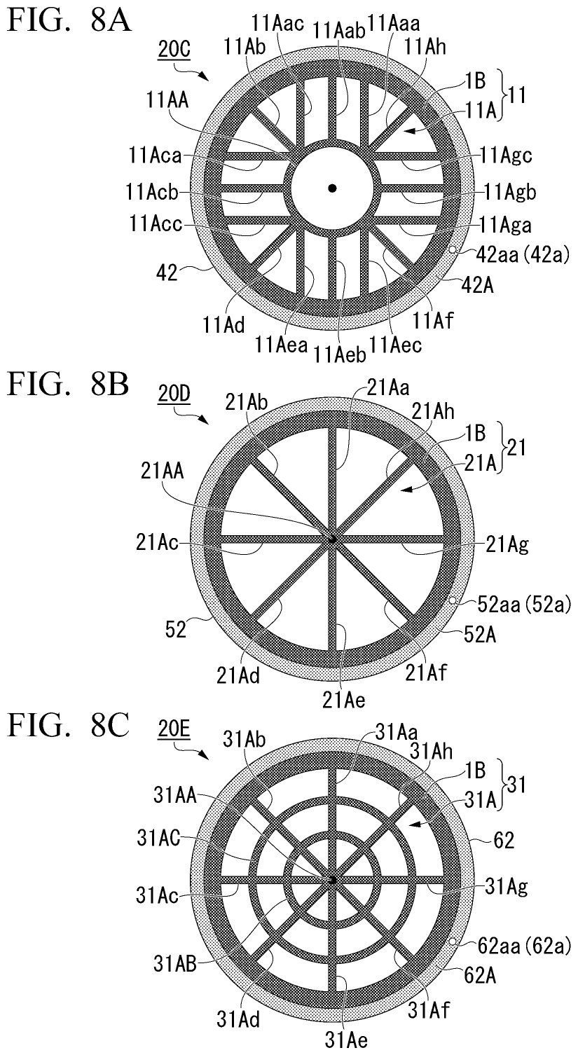

FIGS. 8A to 8C are schematic plan views illustrating configurations of another modified examples of the wafer support plate illustrated in FIGS. 6A and 6B. The modified examples illustrated in FIGS. 8A to 8C are different from the wafer support plate 20 illustrated in FIGS. 6A and 6B in the configuration of the flat portion. The each modified example may be different from others in the configuration of the gas introduction pipe.

In the following, the same elements as in the wafer support plate illustrated in FIGS. 6A and 6B will be referred to by the same reference signs and description thereof will be omitted. The same features as the flat portion of the wafer support plate illustrated in FIGS. 6A and 6B will not be described.

The wafer support plate 20C according to Modified Example 3 illustrated in FIG. 8A includes a flat portion 11 configured to support a wafer W and an outer circumferential protruding portion 42 that is disposed in a surrounding shape on an outer circumference of the flat portion 11 and is formed with a larger thickness than the wafer W. The flat portion 11 includes a perforated support portion 11A and an annular support portion 1B, and the annular support portion 1B is disposed outside of the perforated support portion 11A and is configured to support an outer circumferential end portion Wₒ of the wafer W. The perforated support portion 11A includes a ring-shaped portion 11AA with the center O of the flat portion 11 as a circle center, radial linear portions 11Aab, 11Ab, 11Acb, 11Ad, 11Aeb, 11Af, 11Agb, and 11Ah extending radially in a linear shape from the ring-shaped portion 11AA to the annular support portion 1B, and non-radial linear portions 11Aaa, 11Aac, 11Aca, 11Acc, 11Aea, 11Aec, 11Aga, and 11Agc extending non-radially in a linear shape from the ring-shaped portion 11AA to the annular support portion 1B.

The perforated support portion 11A illustrated in FIG. 8A includes a configuration including eight radial linear portions and eight non-radial linear portions, but the number of radial linear portions and the number of non-radial linear portions are not limited to eight and may be seven or less or nine or more. The number of radial linear portions and the number of non-radial linear portions may be different.

The outer circumferential protruding portion 42 includes a gas introduction pipe 42a including a gas introduction hole 42aa disposed in a top surface 42A, a gas discharge hole (not illustrated) disposed in an inner circumferential sidewall, and a gas flow channel (not illustrated) allowing the gas introduction hole 42aa and the gas discharge hole (not illustrated) to communicate with each other. The gas flow channel may include a configuration in which it does not circulate in the outer circumferential protruding portion but connects the gas introduction hole and the gas discharge hole as illustrated in FIG. 6B or may include a configuration in which it circulates in the outer circumferential protruding portion and connects the gas introduction hole and the gas discharge hole as illustrated in FIGS. 7A and 7B.

The gas introduction pipe 42a may include a configuration in which it is formed to circulate over one round of the outer circumferential protruding portion 42 and introduces gas from the gas discharge holes disposed at equal intervals or at unequal intervals (see FIG. 7A).

The gas introduction pipe 42a may include a configuration in which it is formed in a surrounding shape in an arbitrary length less than one round of the outer circumferential protruding portion 42 and introduces gas from the gas discharge holes disposed at equal intervals or at unequal intervals (see FIG. 7B).

The wafer support plate 20D according to Modified Example 4 illustrated in FIG. 8B includes a flat portion 21 configured to support a wafer W and an outer circumferential protruding portion 52 that is disposed in a surrounding shape on an outer circumference of the flat portion 21 and is formed with a larger thickness than the wafer W. The flat portion 21 includes a perforated support portion 21A and an annular support portion 1B, and the annular support portion 1B is disposed outside of the perforated support portion 21A and is configured to support an outer circumferential end portion Woof the wafer W. The perforated support portion 21A does not include a ring-shaped portion, but includes a point-shaped portion 21AA at the center O of the flat portion 21 and radial linear portions 21Aa, 21Ab, 21Ac, 21Ad, 21Ae, 21Af, 21Ag, and 21Ah extending radially in a linear shape from the point-shaped portion 21AA to the annular support portion 1B instead.

The perforated support portion 21A illustrated in FIG. 8B includes a configuration including eight radial linear portions, but the number of radial linear portions is not limited to eight and may be seven or less or nine or more.

The outer circumferential protruding portion 52 includes a gas introduction pipe 52a including a gas introduction hole 52aa disposed in a top surface 52A, a gas discharge hole (not illustrated) disposed in an inner circumferential sidewall, and a gas flow channel (not illustrated) allowing the gas introduction hole 52aa and the gas discharge hole (not illustrated) to communicate with each other. The gas flow channel may include a configuration in which it does not circulate in the outer circumferential protruding portion but connects the gas introduction hole and the gas discharge hole as illustrated in FIG. 6B or may include a configuration in which it circulates in the outer circumferential protruding portion and connects the gas introduction hole and the gas discharge hole as illustrated in FIGS. 7A and 7B.

The gas introduction pipe 52a may include a configuration in which it is formed to circulate over one round of the outer circumferential protruding portion 52 and introduces gas from the gas discharge holes disposed at equal intervals or at unequal intervals (see FIG. 7A).

The gas introduction pipe 52a may include a configuration in which it is formed in a surrounding shape in an arbitrary length less than one round of the outer circumferential protruding portion 52 and introduces gas from the gas discharge holes disposed at equal intervals or at unequal intervals (see FIG. 7B).

The wafer support plate 20E according to Modified Example 5 illustrated in FIG. 8C includes a flat portion 31 configured to support a wafer W and an outer circumferential protruding portion 62 that is disposed in a surrounding shape on an outer circumference of the flat portion 31 and is formed with a larger thickness than the wafer W. The flat portion 31 includes a perforated support portion 31A and an annular support portion 1B, and the annular support portion 1B is disposed outside of the perforated support portion 31A and is configured to support an outer circumferential end portion Wₒ of the wafer W. The perforated support portion 31A includes a point-shaped portion 31AA at the center O of the flat portion 31, ring-shaped portions 31AB and 31AC disposed concentrically with the center O as the center of concentric circles, and radial linear portions 31Aa, 31Ab, 31Ac, 31Ad, 31Ae, 31Af, 31Ag, and 31Ah extending radially in a linear shape from the point-shaped portion 31AA to the annular support portion 1B.

The perforated support portion 31A illustrated in FIG. 8C includes a configuration including eight radial linear portions, but the number of radial linear portions is not limited to eight and may be seven or less or nine or more.

The perforated support portion 31A illustrated in FIG. 8C includes a configuration including two ring-shaped portions, but the number of ring-shaped portions is not limited to two and may be one or three or more.

The outer circumferential protruding portion 62 includes a gas introduction pipe 62a including a gas introduction hole 62aa disposed in a top surface 62A, a gas discharge hole (not illustrated) disposed in an inner circumferential sidewall, and a gas flow channel (not illustrated) allowing the gas introduction hole 62aa and the gas discharge hole (not illustrated) to communicate with each other. The gas flow channel may include a configuration in which it does not circulate in the outer circumferential protruding portion but connects the gas introduction hole and the gas discharge hole as illustrated in FIG. 6B or may include a configuration in which it circulates in the outer circumferential protruding portion and connects the gas introduction hole and the gas discharge hole as illustrated in FIGS. 7A and 7B.

The gas introduction pipe 62a may include a configuration in which it is formed to circulate over one round of the outer circumferential protruding portion 62 and introduces gas from the gas discharge holes disposed at equal intervals or at unequal intervals (see FIG. 7A).

The gas introduction pipe 62a may include a configuration in which it is formed in a surrounding shape in an arbitrary length less than one round of the outer circumferential protruding portion 62 and introduces gas from the gas discharge holes disposed at equal intervals or at unequal intervals (see FIG. 7B).

[Semiconductor Manufacturing Apparatus]

### First Embodiment

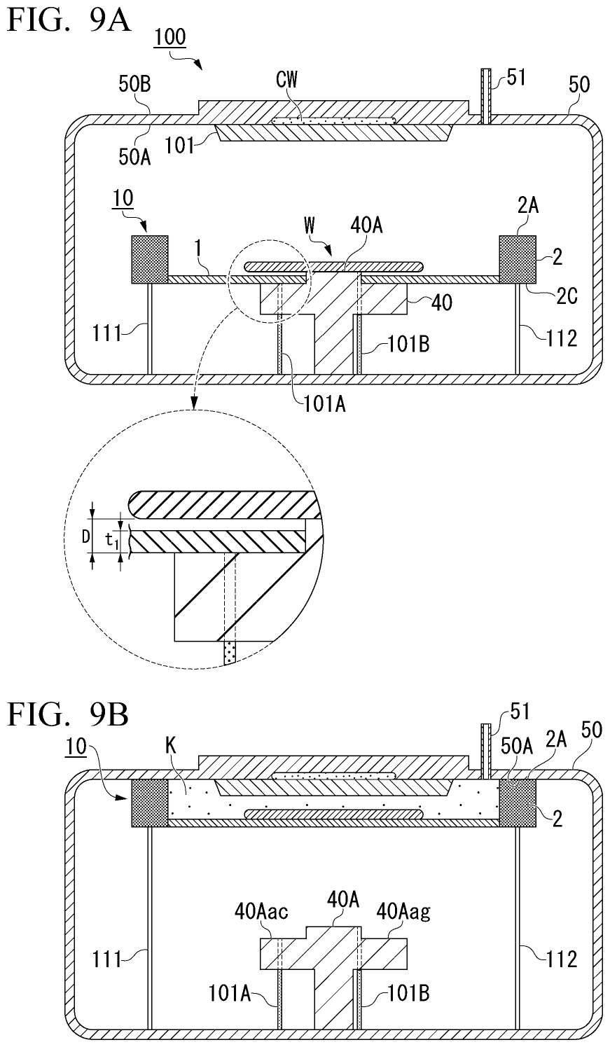

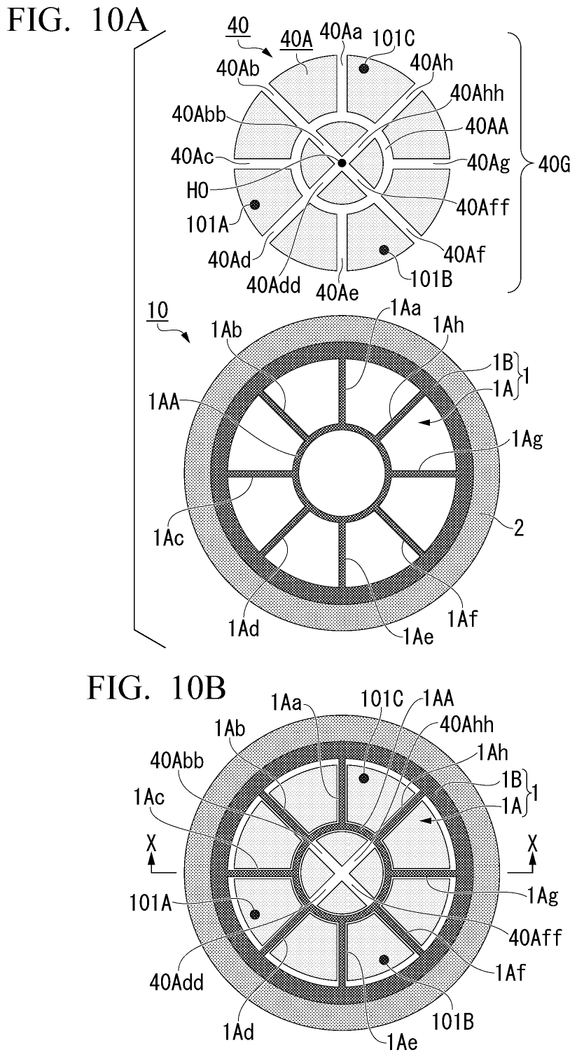

FIGS. 9A and 9B are schematic sectional views illustrating a configuration of a semiconductor manufacturing apparatus according to a first embodiment, where FIG. 9A illustrates a setup when a film is formed and FIG. 9B illustrates a setup when a wafer W is cooled. FIGS. 10A and 10B are diagrams illustrating a relationship between a configuration of a wafer support member and a configuration of a heater table according to the present disclosure, where FIG. 10A is a schematic plan view in a state in which the wafer support plate is not still placed on a heater table and FIG. 10B is a schematic plan view in a state in which the wafer support plate is placed on the heater table.

A semiconductor manufacturing apparatus 100 illustrated in FIGS. 9A and 9B includes the wafer support plate 10 illustrated in FIGS. 1A and 1B, a heater table 40 including a mounting surface 40A configured to mount the wafer W and including a groove pattern 40G (see FIG. 10A) formed on the mounting surface 40A, a moving mechanism configured to move the wafer support plate 10 in the vertical direction, a chamber 50 accommodating the wafer support plate 10 and the heater table 40, and a gas supply pipe 51 disposed in an outer wall of the chamber 50. A part of the perforated support portion 1A of the wafer support plate 10 is accommodated in the groove pattern 40G.

In this specification, “a part of a perforated support portion is accommodated in a groove” or “a part of a perforated support portion is accommodated in a groove pattern” means that a part of the perforated support portion enters the groove such that the top surface of the perforated support portion is located lower than the mounting surface of the heater table. In this way, the wafer support plate and the heater table are formed such that the depth D of the groove pattern 40G and the thickness t₁ of the perforated support portion 1A satisfy a relationship D>t₁. Accordingly, when a wafer is mounted on the mounting surface of the heater table, the perforated support portion does not come into contact with the wafer.

As long as it includes a configuration including a way that heats a wafer W and forms a film on the wafer W, a known semiconductor manufacturing apparatus that forms a film, for example, using a sputtering method, a chemical vapor deposition (hereinafter abbreviated to CVD) method, or a vapor deposition method may be used as the semiconductor manufacturing apparatus 100, and the semiconductor manufacturing apparatus 100 is not particularly limited. Alternatively, as long as it includes a configuration including a way that supercools and processes a wafer W, a known semiconductor manufacturing apparatus that removes a material on the wafer, for example, using a plasma etching method may be used, and the semiconductor manufacturing apparatus 100 is not particularly limited. In the following description, a semiconductor manufacturing apparatus that cools a heated wafer after forming a film on the wafer using the sputtering method will be described as the film forming apparatus, and it will be easily understood that a device that returns (heats) a supercooled wafer to a normal temperature after etching the wafer may be constructed as the semiconductor manufacturing apparatus by appropriately changing members or the like.

The semiconductor manufacturing apparatus 100 illustrated in FIGS. 9A and 9B is, for example, a semiconductor manufacturing apparatus that can form a metal film using the sputtering method. Reference sign 101 is a sputtering target. In the semiconductor manufacturing apparatus 100, a coolant CW is made to flow in the vicinity of the sputtering target 101 on the outer wall 50B of the chamber 50 to cool the sputtering target 101.

For example, a substantially cylindrical chamber formed of metal such as aluminum or SUS may be used as the chamber 50, but the chamber 50 is not limited thereto.

A heater table of a type that allows a wafer to be mounted and heats the wafer may be used as the heater table 40. Typical examples of the heater table 40 include a resistance heating type and an induction heating type.

Since the heater table 40 needs to efficiently transfer heat from a heater to a wafer and to include corrosion resistance to film-forming gas, etching gas, or the like, a ceramic material is often used as the material of the heater table 40 in order to keep an insulation, but the material is not limited thereto.

The groove pattern 40G is formed on the mounting surface 40A of the heater table 40.

In the heater table 40 illustrated in FIG. 10A, the groove pattern 40G includes grooves 40Aa, 40Ab, 40Ac, 40Ad, 40Ae, 40Af, 40Ag, 40Ah, 40Abb, 40Add, 40Aff, 40Ahh, and 40AA. The mounting surface 40A includes a circular shape in a plan view in the Z direction, and the groove pattern 40G is symmetrically formed with respect to the center HO of the circle. That is, the groove pattern 40G includes a ring-shaped groove 40AA with the center HO of the groove pattern 40G as a circle center, eight radial grooves 40Aa, 40Ab, 40Ac, 40Ad, 40Ae, 40Af, 40Ag, and 40Ah extending radially in a linear shape from the ring-shaped groove 40AA, linear grooves 40Abb and 40Aff connecting the radial grooves 40Ab and 40Af, and linear grooves 40Add and 40Ahh connecting the radial grooves 40Ad and 40Ah. The radial grooves 40Ab and 40Af and the linear grooves 40Abb and 40Aff are grooves communicating linearly via the center HO. The radial grooves 40Ad and 40Ah and the linear grooves 40Add and 40Ahh are grooves communicating linearly via the center HO.

The perforated support portion 1A of the wafer support plate 10 is formed such that it can be accommodated in the grooves of the groove pattern 40G on the mounting surface 40A of the heater table 40.

The ring-shaped portion 1AA of the perforated support portion 1A is accommodated in the groove 40AA, and the eight radial linear portions 1Aa, 1Ab, 1Ac, 1Ad, 1Ae, 1Af, 1Ag, and 1Ah of the perforated support portion 1A are accommodated in the grooves 40Aa, 40Ab, 40Ac, 40Ad, 40Ae, 40Af, 40Ag, and 40Ah, respectively. As illustrated in FIG. 9A, the thickness t₁ of the perforated support portion 1A is set to be smaller than the depth D of the groove pattern 40G. With this configuration, when the wafer support plate 10 is mounted on the mounting surface 40A of the heater table 40, the perforated support portion 1A is accommodated in the grooves of the groove pattern 40G.

When a wafer W is mounted on the mounting surface of the heater table mounted on the wafer support plate 10, the linear portions do not come into contact with the wafer.

The groove pattern 40G on the mounting surface 40A of the heater table 40 may be used as a groove in which inert gas such as Ar flows when a wafer W is mounted on the heater table 40 and is heated. In this case, the groove may be commonly used as the groove in which the wafer support plate 10 is accommodated separately from the wafer W and as the groove in which inert gas such as Ar flows.

The semiconductor manufacturing apparatus 100 illustrated in FIG. 9A includes support pins 111 and 112 supporting the bottom surface of the outer circumferential protruding portion 2 of the wafer support plate 10 and can move the wafer support plate 10 in the vertical direction by causing a moving mechanism (not illustrated) to vertically move the support pins 111 and 112. In the semiconductor manufacturing apparatus 100 illustrated in FIG. 9A, the support pins 111 and 112 supports the outer circumferential protruding portion 2 from the bottom surface 2C of the outer circumferential protruding portion 2 of the wafer support plate 10, but the present disclosure is not limited thereto and the semiconductor manufacturing apparatus 100 may include a lifting mechanism that lifts the wafer support plate 10 upward from an upper part of the chamber. The lifting mechanism will be described later in detail.

The semiconductor manufacturing apparatus 100 illustrated in FIG. 9A includes lift pins 101A, 101B, and 101C supporting a wafer W from the backside of the wafer W. The lift pins 101A, 101B, and 101C are inserted into through-holes of the heater table 40, and bottom ends of the lift pins 101A, 101B, and 101C are supported by a lifting shaft (not illustrated). By lifting the lifting shaft up and down, the lift pins 101A, 101B, and 101C move up and down, and upper ends of the lift pins 101A, 101B, and 101C can lift the wafer W up and down.

The semiconductor manufacturing apparatus 100 illustrated in FIG. 9A includes three lift pins, but the number of lift pins is not limited to three and may be four or more. The positions at which the lift pins are disposed are examples, and the lift pins may be disposed at different positions.

An example of a process flow from formation of a film on a wafer W to cooling of the film-formed wafer W in the semiconductor manufacturing apparatus 100 illustrated in FIGS. 9A and 9B will be described below.

First, the wafer support plate 10 on which a wafer W is mounted is mounted on the heater table 40 (see FIG. 9A). At this time, the wafer support plate 10 is mounted on the heater table 40 such that the perforated support portion 1A of the wafer support plate 10 is accommodated in the grooves of the groove pattern 40G on the mounting surface 40A of the heater table 40. When the perforated support portion 1A of the wafer support plate 10 is accommodated in the grooves of the groove pattern 40G of the heater table 40, the upper end of the perforated support portion 1A is disposed at a position lower than the mounting surface 40A. At this time, since the wafer W is mounted on the mounting surface 40A and the backside of the wafer W is located flush with the mounting surface 40A, the wafer support plate 10 is separated from the wafer W.

Then, for example, a metal film is formed on the wafer W while heating the wafer W using the heater table 40.

Then, the wafer W is separated from the mounting surface 40A of the heater table 40 using the lift pins 101A, 101B, and 101C, and the outer circumferential protruding portion 2 of the wafer support plate 10 is pushed up using the support pins 111 and 112 to lift the wafer support plate 10 upward with the wafer W mounted on the perforated support portion 1A of the wafer support plate 10. At this time, since the wafer W is mounted on the perforated support portion 1A of the wafer support plate 10 with lifting-up of the wafer support plate 10 and the wafer W can move upward along with the wafer support plate 10 without using the lift pins 101A, 101B, and 101C, upward movement of the wafer support plate 10 and the wafer W may be performed using only the support pins 111 and 112.

With upward movement of the wafer support plate 10 and the wafer W, the top surface 2A of the outer circumferential protruding portion 2 of the wafer support plate 10 is brought into contact with the inner wall 50A of the chamber 50 (see FIG. 9B). At this time, a closed space K is formed by the inner wall 50A of the chamber 50, the outer circumferential protruding portion 2 of the wafer support plate 10, and the wafer W.

Then, cooling gas (for example, Ar gas) is introduced into the closed space K via the gas supply pipe 51. The cooling gas introduced into the closed space K is cooled by thermal conduction from the inner wall 50A to the outer wall 50B by cooling the outer wall 50B using a coolant flowing in the outer wall 50B of the chamber 50. Since the closed space K is full of the cooling gas, thermal conductivity via gas in a space between the sputtering target 101 and the wafer W cooled with the coolant is enhanced and cooling efficiency of the wafer W is enhanced.

When a semiconductor manufacturing apparatus not including the sputtering target 101 is used, the wafer W is cooled through thermal conduction between the inner wall 50A of the chamber 50 cooled with the coolant and the wafer W.

Since a high-vacuum atmosphere can be maintained in a space other than the closed space K, it is possible to cut off thermal conduction from the heater table 40 to the wafer W or thermal conduction to the chamber atmosphere and to curb a change in temperature of the heater table 40.

During cooling of the wafer W, the pressure of the closed space K into which the cooling gas is introduced may be set to, for example, 1 Torr to 10 Torr (133 Pa to 1333 Pa), and the pressure in the chamber other than the closed space K can be set to, for example, about 10 mTorr (1.33 Pa).

As described above, with the semiconductor manufacturing apparatus according to the present disclosure, a metal film can be formed on a wafer while heating the wafer using the heater table, the wafer W can be moved to the vicinity of the sputtering target using a moving and support mechanism for separating the wafer from the heater table in a same chamber after completing the formation of the film, and the wafer can be cooled.

Since the wafer can be cooled without transporting the wafer to a chamber other than the chamber in which film formation is performed, it is possible to shorten the time from formation of a film to start of cooling and to improve a thermal history of a metal film. Since the wafer is separated from the heater table, it is possible to minimize a change in temperature of the heater table and to minimize an influence on formation of a film on another wafer W to be continued.

### Modified Examples 1 to 3

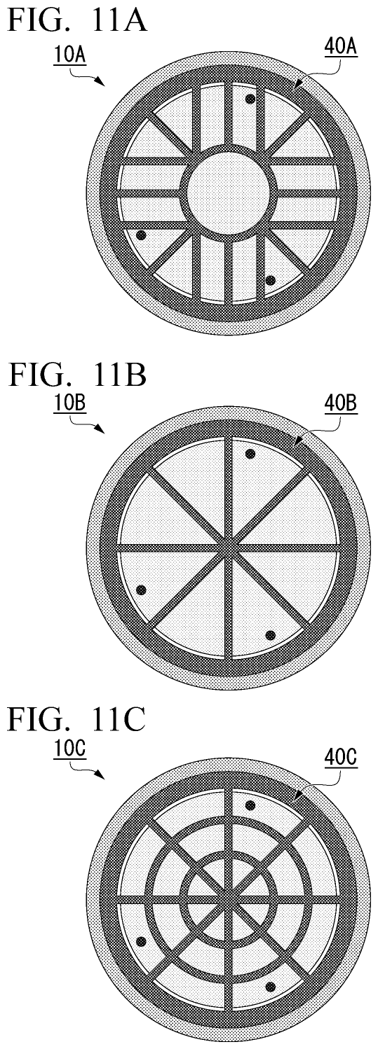

FIGS. 11A to 11C are schematic plan views illustrating configurations of another modified examples of the heater table illustrated in FIGS. 10A to 10BB. The heater tables illustrated in FIGS. 11A to 11C are heater tables corresponding to the wafer support plate 10A, the wafer support plate 10B, and the wafer support plate 10C illustrated in FIGS. 4 and 5 and FIGS. 6A and 6B, respectively. A heater table corresponding to a wafer support plate means that the perforated support portion of the wafer support plate is accommodated in the grooves of the groove pattern on the mounting surface of the heater table. In other words, it means that the perforated support portion of the wafer support plate is mounted on the heater table in a state in which the perforated support portion is not in contact with a wafer when the wafer is mounted on the mounting surface of the heater table.

FIGS. 11A to 11C are schematic plan views in a state in which the wafer support plate 10A, the wafer support plate 10B, and the wafer support plate 10C are mounted on the heater tables 40A, 40B, and 40C, respectively.

### Second Embodiment

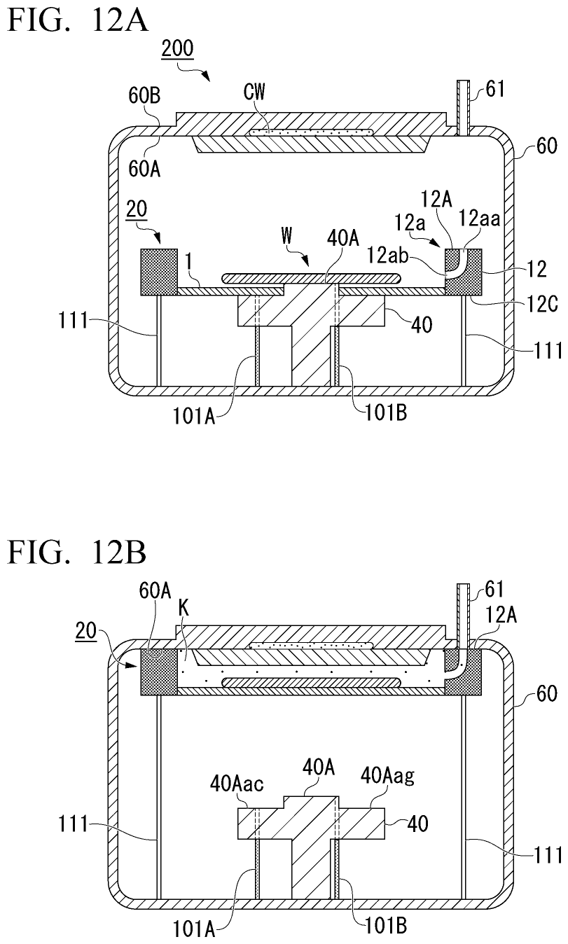

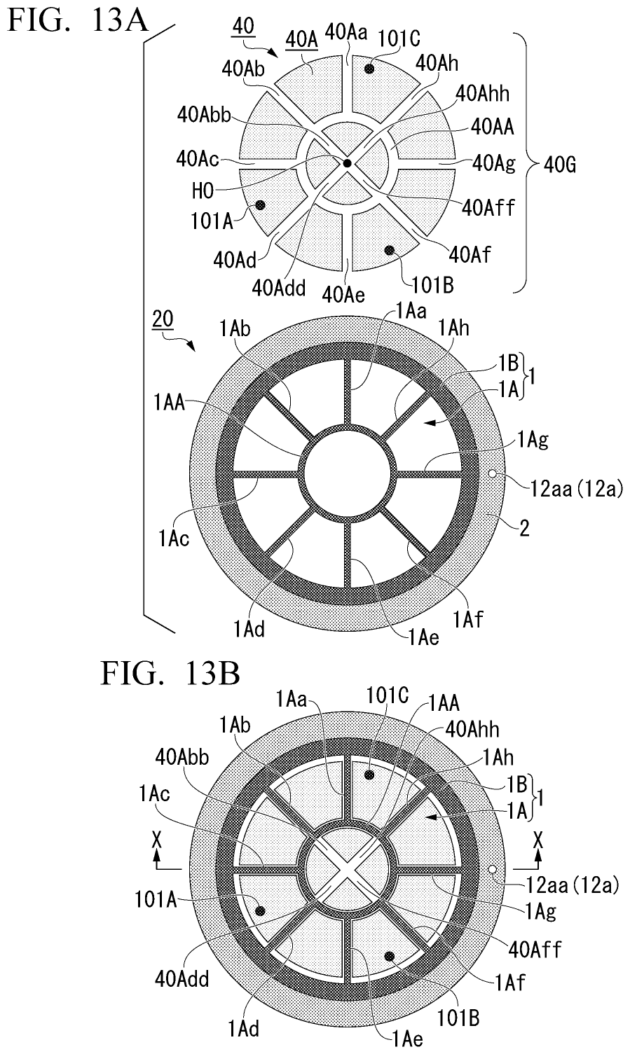

FIGS. 12A and 12B are schematic sectional views illustrating a configuration of a semiconductor manufacturing apparatus according to a second embodiment, where FIG. 12A illustrates a setup when a film is formed and FIG. 12B illustrates a setup when a wafer W is cooled. FIGS. 13A and 13B are diagrams illustrating a relationship between a configuration of a wafer support plate and a configuration of a heater table according to the present disclosure, where FIG. 13A is a schematic plan view in a state in which the wafer support plate is not still placed on a heater table and FIG. 13B is a schematic plan view in a state in which the wafer support plate is placed on the heater table.

The semiconductor manufacturing apparatus according to the second embodiment is mainly different from the semiconductor manufacturing apparatus according to the first embodiment in that the outer circumferential protruding portion of the wafer support plate includes a gas introduction pipe.

In the following description, the same elements as in the semiconductor manufacturing apparatus according to the first embodiment will be referred to by the same reference signs, and description thereof will be omitted.

A semiconductor manufacturing apparatus 200 illustrated in FIGS. 12A and 12B includes the wafer support plate 20 illustrated in FIGS. 6A and 6B, a heater table 40 including a mounting surface 40A configured to mount the wafer W and including a groove pattern 40G (see FIG. 10A) formed on the mounting surface 40A, a moving mechanism configured to move the wafer support plate 20 in the vertical direction, a chamber 60 accommodating the wafer support plate 20 and the heater table 40, and a gas supply pipe 61 disposed in an outer wall of the chamber 60. The perforated support portion 1A of the wafer support plate 20 is accommodated in the groove pattern 40G.

The gas supply pipe 61 may serve also as a gas discharge pipe. The gas discharge pipe can be disposed in the outer wall of the chamber separately from the gas supply pipe 61.

In the semiconductor manufacturing apparatus 200 illustrated in FIGS. 12A and 12B, when the wafer support plate 20 is moved upward to bring the top surface 12A of the outer circumferential protruding portion 12 of the wafer support plate 20 into contact with the inner wall 61A of the chamber 60 at the time of cooling a wafer W, the gas introduction hole 12aa disposed in the top surface 12A of the outer circumferential protruding portion 12 communicates with the gas supply pipe 61 disposed in the outer wall of the chamber 60.

With the semiconductor manufacturing apparatus 200 illustrated in FIGS. 12A and 12B, since the gas introduction hole 12aa is disposed in the top surface 12A of the outer circumferential protruding portion 12 of the wafer support plate 20, a cooling gas from the gas supply pipe 61 disposed in the outer wall of the chamber 60 can be introduced from the top surface 12A of the outer circumferential protruding portion 12 and thus a diameter of the wafer support plate 20 can be set to be smaller than that of the semiconductor manufacturing apparatus 100 illustrated in FIGS. 9A and 9B. As a result, a diameter of the chamber itself can be set to be smaller than that in the semiconductor manufacturing apparatus 100 illustrated in FIGS. 9A and 9B.

The heater table 40 illustrated in FIG. 13A includes the same configuration as the heater table 40 illustrated in FIG. 10A.

On the other hand, the wafer support plate 20 illustrated in FIG. 13A is different from the wafer support plate 10 illustrated in FIG. 10A in that the gas introduction pipe 12a is disposed in the outer circumferential protruding portion of the wafer support plate.

### Modified Examples 1 to 3

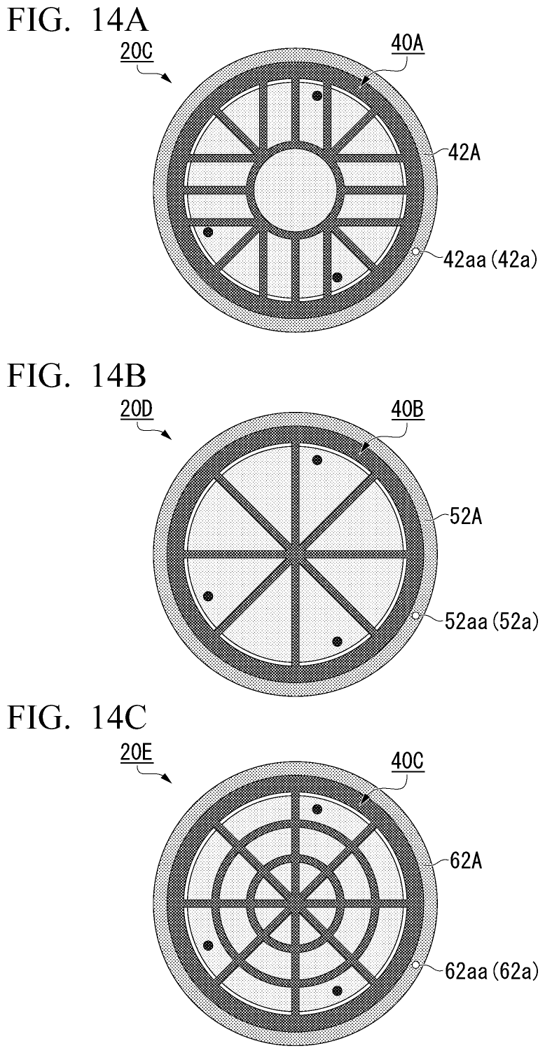

FIGS. 14A to 14C are schematic plan views illustrating configurations of another modified examples of the heater tables illustrated in FIGS. 13A to 13B. The heater tables 40A, 40B, and 40C illustrated in FIGS. 14A to 14C are heater tables corresponding to the wafer support plate 20C, the wafer support plate 20D, and the wafer support plate 20E illustrated in FIGS. 8A to 8C, respectively. FIGS. 14A to 14C are schematic plan views in a state in which the wafer support plate 20C, the wafer support plate 20D, and the wafer support plate 20E are mounted on the heater tables 40A, 40B, and 40C, respectively.

The wafer support plate 20C illustrated in FIG. 14A includes a gas introduction pipe 42a including a gas introduction hole 42aa disposed in the top surface 42A, a gas discharge hole (not illustrated) disposed in the inner circumferential sidewall, and a gas flow channel (not illustrated) allowing the gas introduction hole 42aa and the gas discharge hole (not illustrated) to communicate with each other. The gas flow channel may include a configuration in which it does not circulate in the outer circumferential protruding portion but connects the gas introduction hole and the gas discharge hole as illustrated in FIG. 6B or may include a configuration in which it circulates in the outer circumferential protruding portion and connects the gas introduction hole and the gas discharge hole as illustrated in FIGS. 7A and 7B.

The heater table 40A illustrated in FIG. 14A includes a groove pattern in which the perforated support portion of the wafer support plate 20C can be accommodated on the mounting surface.

The wafer support plate 20D illustrated in FIG. 14B includes a gas introduction pipe 52a including a gas introduction hole 52aa disposed in the top surface 52A, a gas discharge hole (not illustrated) disposed in the inner circumferential sidewall, and a gas flow channel (not illustrated) allowing the gas introduction hole 52aa and the gas discharge hole (not illustrated) to communicate with each other. The gas flow channel may include a configuration in which it does not circulate in the outer circumferential protruding portion but connects the gas introduction hole and the gas discharge hole as illustrated in FIG. 6B or may include a configuration in which it circulates in the outer circumferential protruding portion and connects the gas introduction hole and the gas discharge hole as illustrated in FIGS. 7A and 7B.

The heater table 40B illustrated in FIG. 14B includes a groove pattern in which the perforated support portion of the wafer support plate 20D can be accommodated on the mounting surface.

The wafer support plate 20E illustrated in FIG. 14C includes a gas introduction pipe 62a including a gas introduction hole 62aa disposed on the top surface 62A, a gas discharge hole (not illustrated) disposed in the inner circumferential sidewall, and a gas flow channel (not illustrated) allowing the gas introduction hole 62aa and the gas discharge hole (not illustrated) to communicate with each other. The gas flow channel may include a configuration in which it does not circulate in the outer circumferential protruding portion but connects the gas introduction hole and the gas discharge hole as illustrated in FIG. 6B or may include a configuration in which it circulates in the outer circumferential protruding portion and connects the gas introduction hole and the gas discharge hole as illustrated in FIGS. 7A and 7B.

The heater table 40C illustrated in FIG. 14C includes a groove pattern in which the perforated support portion of the wafer support plate 20E can be accommodated on the mounting surface.

### Third Embodiment

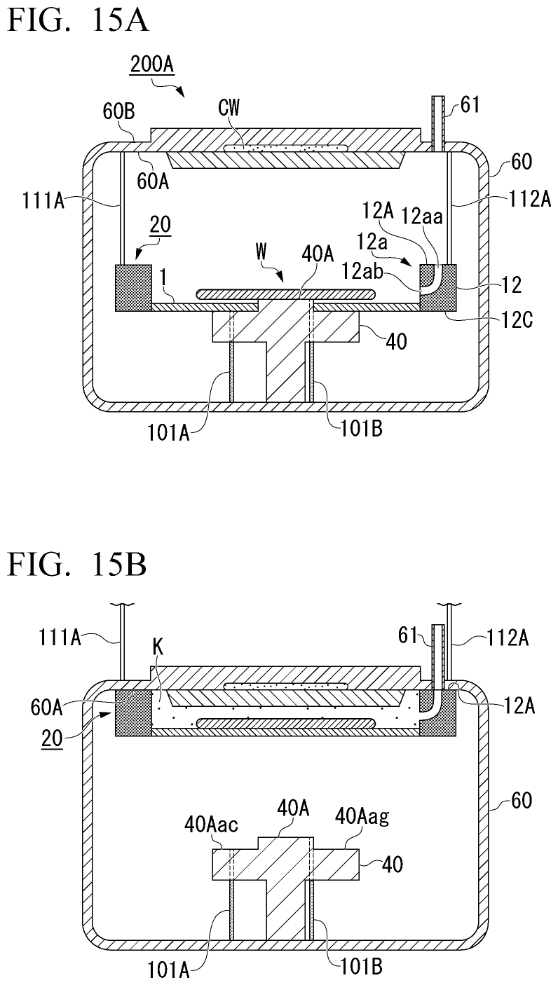

FIGS. 15A and 15B are schematic sectional views illustrating a configuration of a semiconductor manufacturing apparatus according to a third embodiment, where FIG. 15A illustrates a setup when a film is formed and FIG. 15B illustrates a setup when a wafer W is cooled.

The semiconductor manufacturing apparatus according to the third embodiment is mainly different from the semiconductor manufacturing apparatus according to the second embodiment in that the support pins are configured to support the outer circumferential protruding portion of the wafer support plate from the top surface of the outer circumferential protruding portion (a lifting mechanism). The example illustrated in FIGS. 15A and 15B is an example in which the configuration in which the support pins support the bottom surface of the outer circumferential protruding portion of the wafer support plate in the semiconductor manufacturing apparatus according to the second embodiment is replaced with the configuration (the lifting mechanism) in which the support pins support the top surface of the outer circumferential protruding portion of the wafer support plate from above, but the configuration in which the support pins support the bottom surface of the outer circumferential protruding portion of the wafer support plate in the semiconductor manufacturing apparatus according to the first embodiment may be replaced with a configuration (the lifting mechanism) in which the support pins support the top surface of the outer circumferential protruding portion of the wafer support plate from above.

In the following description, the same elements as in the semiconductor manufacturing apparatus according to the second embodiment will be referred to by the same reference signs, and description thereof will be omitted.

A semiconductor manufacturing apparatus 200A illustrated in FIG. 15A includes the wafer support plate 20 illustrated in FIGS. 6A and 6B, a heater table 40 including a mounting surface 40A on which a wafer W is mounted and including a groove pattern 40G (see FIG. 10A) formed on the mounting surface 40A, a moving mechanism configured to move the wafer support plate 20 in the vertical direction, a chamber 60 accommodating the wafer support plate 20 and the heater table 40, and a gas supply pipe 61 disposed in an outer wall of the chamber 60. The perforated support portion 1A of the wafer support plate 20 is accommodated in the groove pattern 40G.

The semiconductor manufacturing apparatus 200A illustrated in FIG. 15A includes support pins 111A and 112A supporting the top surface 12A of the outer circumferential protruding portion 12 of the wafer support plate 20 and can move the wafer support plate 20 in the vertical direction by causing a moving mechanism (not illustrated) to vertically move the support pins 111A and 112A. The support pins 111A and 112A penetrate the outer wall 60B from the inner wall 60A in the upper part of the chamber 60, but the present disclosure is not limited thereto. For example, a space into which the support pins 111A and 112A retreat may be disposed in the chamber 60.

In the semiconductor manufacturing apparatus 200A illustrated in FIG. 15B, when the wafer support plate 20 is moved upward to bring the top surface 12A of the outer circumferential protruding portion 12 of the wafer support plate 20 into contact with the inner wall 60A of the chamber 60 at the time of cooling a wafer W, the gas introduction hole 12aa disposed in the top surface 12A of the outer circumferential protruding portion 12 communicates with the gas supply pipe 61 disposed in the outer wall of the chamber 60.

One merit for a configuration employing the lifting mechanism is that guide holes for the support pins 111A and 112A can be formed in the inner wall 60A of the chamber 60 when the wafer support plate 20 is moved to a cooling position, and thus accuracy of contact positioning between the outer circumferential protruding portion 12 of the wafer support plate 20 and the inner wall 60A of the chamber 60 can be likely to be improved. Accordingly, it is possible to improve accuracy of positioning between the gas supply pipe 61 and the holes of the top surface 12A of the outer circumferential protruding portion 12. That is, since gas can flow into and out of the closed space K, it is possible to reduce factors of hindering flowing-in/out of gas due to misalignment.

In aligning the grooves of the heater table 40 and the linear portions of the wafer support plate 20, since gas flows on the backside at the time of formation of a film and thus the width of the grooves of the heater table 40 is set to be slightly larger than the width of the linear portions, a margin, so-called clearance, for alignment of the gas supply pipe 61 is great and thus a problem is less likely to occur even when priority is given to alignment of the gas supply pipe 61.

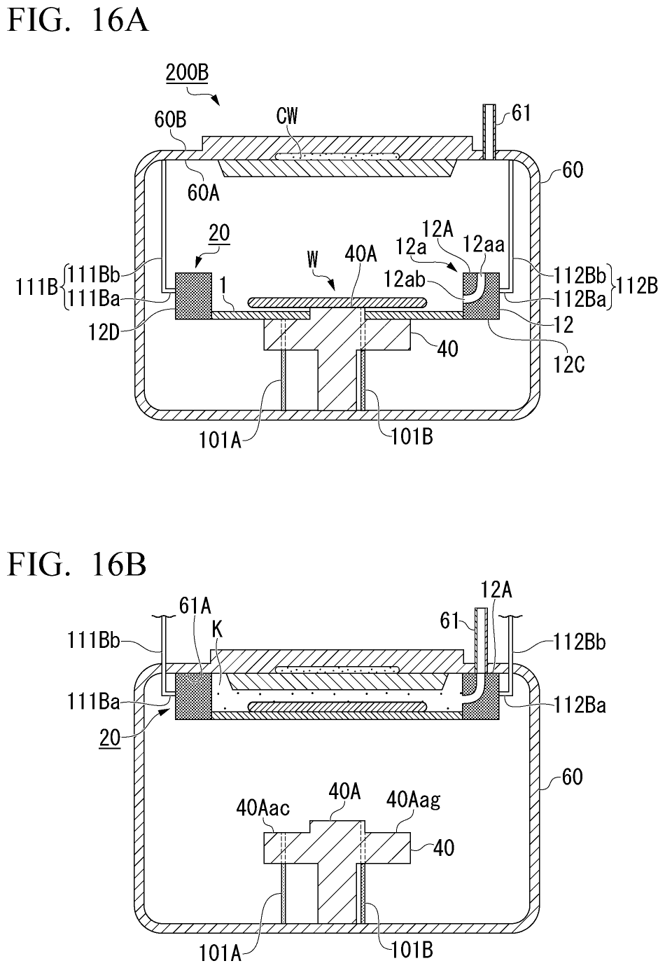

FIGS. 16A and 16B illustrates a modified example of the semiconductor manufacturing apparatus 200A illustrated in FIGS. 15A and 15B, where FIG. 16A illustrates a setup when a film is formed and FIG. 16B illustrates a setup when a wafer W is cooled.

The semiconductor manufacturing apparatus 200B illustrated in FIGS. 16A and 16B is different from the semiconductor manufacturing apparatus 200A illustrated in FIGS. 15A and 15B in the configuration of the support pins.

Support pins 111B and 112B of the semiconductor manufacturing apparatus 200B illustrated in FIGS. 16A and 16B include first parts 111Ba and 112Ba protruding from an outer circumferential side surface 12D of the outer circumferential protruding portion 12 of the wafer support plate 20 and second parts 111Bb and 112Bb connected to the first parts 111Ba and 112Ba and extending upward. In FIGS. 16A and 16B, for example, the first parts protrude in the horizontal direction, and the second parts extend in the vertical direction, but the protruding direction and the extending direction of the parts are not limited thereto. For example, the first parts may extend obliquely upward from the outer circumferential side surface 12D, and the second parts may be connected to the first parts, extend obliquely upward at another angle different from the angle of the obliquely upward extending of the first parts, and extend in the vertical direction on the way. Alternatively, for example, the first parts may protrude from the outer circumferential side surface 12D in an arc shape of a ¼ circle such that the direction changes from the horizontal direction to the vertical direction, and the second parts may be connected to the first parts and extend in the vertical direction. The first parts protruding from the outer circumferential side surface 12D and the second parts extending upward may include other shapes described above as one example.

In FIGS. 15A and 15B and FIGS. 16A and 16B, an example in which the wafer support plate in which the gas introduction pipe is disposed in the outer circumferential protruding portion is used is illustrated, but the present disclosure may be applied to an example in which the wafer support plate in which the gas introduction pipe is not disposed in the outer circumferential protruding portion is used.

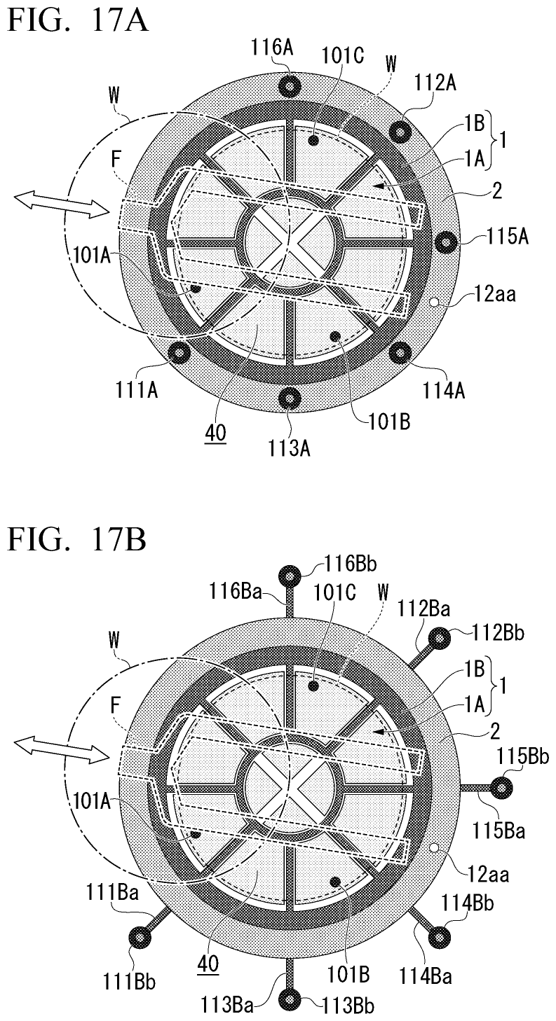

FIGS. 17A and 17B illustrate an example of positions of the support pins illustrated in FIGS. 15A and 15B and FIGS. 16A and 16B, respectively. The positions of the support pins are needed to be set to positions at which transportation of a wafer is not hindered.

As illustrated in FIG. 17A, a plate with a shape of a fork F for transporting a wafer W is inserted between the backside of the wafer W lifted up by the lift pins 101A, 101B, and 101C and the heater table 40, the wafer W is mounted on the fork F by bringing the backside of the wafer W and the fork F into contact with each other by lifting down the lift pins 101A, 101B, and 101C or lifting up the fork F, and the wafer W is taken into or out. Here, an example of the positional relationship between the size of the fork F and the insertion position is illustrated in the drawings. The positional relationship is needed to be set such that the fork F does not come into contact with the lift pins 101A, 101B, and 101C and the support pins 111A, 112A, 113A, 114A, 115A, and 116A of the lifting mechanism.

Similarly, as illustrated in FIG. 17B, the positional relationship is needed to be set such that the fork F does not come into contact with the lift pins 101A, 101B, and 101C and the support pins 111Ba, 111Bb, 112Ba, 112Bb, 113Ba, 113Bb, 114Ba, 114Bb, 115Ba, 115Bb, 116Ba, and 116Bb of the lifting mechanism.

According to one aspect, the disclosed embodiments make it possible to provide a wafer support member that can move in the same chamber after a wafer has been processed and enable a temperature adjusting process of the processed wafer.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alternations could be made hereto without departing from the spirit and scope of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer support plate, comprising:
a flat portion configured to support a wafer; and
an outer circumferential protruding portion, being disposed in a surrounding shape on an outer circumference of the flat portion and being formed with a larger thickness than the wafer;
wherein the flat portion comprises a perforated support portion and an annular support portion, and the annular support portion is disposed outside of the perforated support portion and is configured to support an outer circumferential end portion of the wafer.

2. The wafer support plate according to claim 1, wherein a gas introduction pipe extending from a top surface to an inner circumferential sidewall is formed in the outer circumferential protruding portion.

3. The wafer support plate according to claim 1, wherein the perforated support portion comprises a linear portion, the perforated support portion comprises a linear pattern, and the linear pattern is symmetric with respect to a center of the flat portion.

4. The wafer support plate according to claim 3, wherein the perforated support portion comprises a ring-shaped portion centered on the center of the flat portion and a radial linear portion extending radially in a linear shape from the ring-shaped portion to the annular support portion.

5. The wafer support plate according to claim 3, wherein the perforated support portion comprises a radial linear portion extending radially in a linear shape from the center of the flat portion to the annular support portion.

6. The wafer support plate according to claim 3, wherein the perforated support portion comprises a radial linear portion extending radially in a linear shape from the center of the flat portion to the annular support portion and a plurality of ring-shaped portions disposed concentrically with the center of the flat portion as a center of concentric circles.

7. The wafer support plate according to claim 3, wherein the perforated support portion comprises a ring-shaped portion centered the center of the flat portion, a radial linear portion extending radially in a linear shape from the ring-shaped portion to the annular support portion, and a non-radial linear portion extending non-radially in a linear shape from the ring-shaped portion to the annular support portion.

8. The wafer support plate according to claim 1, wherein the perforated support portion comprises a linear portion with a width equal to 3 mm, more than 3 mm and less than 30 mm, or equal to 30 mm.

9. The wafer support plate according to claim 2, wherein the gas introduction pipe of the outer circumferential protruding portion comprises a gas introduction hole disposed in the top surface, a gas discharge hole disposed in the inner circumferential sidewall, and a gas flow channel allowing the gas introduction hole to communicate with the gas discharge hole.

10. The wafer support plate according to claim 9, wherein the gas flow channel is disposed in a surrounding shape in the outer circumferential protruding portion.

11. The wafer support plate according to claim 9, wherein the gas introduction pipe comprises a plurality of gas discharge holes disposed to be separated from each other.

12. The wafer support plate according to claim 1, wherein the wafer support plate is formed with a heat resistant material and a melting point of the heat resistance material is equal to or higher than 500° C.

13. The wafer support plate according to claim 12, wherein the heat resistant material comprises one of a steel use stainless, a titanium alloy, a nickel alloy, a cobalt alloy, a tantalum alloy, and a molybdenum alloy or a combination thereof.

14. A semiconductor manufacturing apparatus, comprising:
the wafer support plate according to claim 1;
a heater table comprising a mounting surface configured to mount the wafer, and a groove pattern being formed on the mounting surface;
a moving mechanism configured to move the wafer support plate in a vertical direction;
a chamber accommodating the wafer support plate and the heater table; and
a gas supply pipe disposed in an outer wall of the chamber;
wherein a part of the perforated support portion in the wafer support plate is accommodated in the groove pattern.

15. The semiconductor manufacturing apparatus according to claim 14, wherein the gas supply pipe serves also as a gas discharge pipe.

16. The semiconductor manufacturing apparatus according to claim 14, further comprising:
a gas discharge pipe disposed in the outer wall of the chamber.

17. The semiconductor manufacturing apparatus according to claim 14, further comprising:
a support pin supporting the outer circumferential protruding portion, wherein the moving mechanism is configured to move the wafer support plate in the vertical direction by moving the support pin in the vertical direction.

18. The semiconductor manufacturing apparatus according to claim 17, wherein the support pin supports the outer circumferential protruding portion with a bottom surface of the outer circumferential protruding portion.

19. The semiconductor manufacturing apparatus according to claim 17, wherein the support pin supports the outer circumferential protruding portion with a top surface of the outer circumferential protruding portion.

20. The semiconductor manufacturing apparatus according to claim 17, wherein the support pin comprises a first part protruding from an outer circumferential side surface of the outer circumferential protruding portion and a second part extending upward to be connected with the first part, and the support pin supports the outer circumferential protruding portion.
